(19) United States
(12) Patent Application Publication
(10) Pub. No.: US 2010/0326523 A1
(43) Pub. Date: Dec. 30, 2010

(54) System and Method for Collecting and Optically Transmitting Solar Radiation

(75) Inventors: Carl Smith, III, Sarasota, FL (US); Robert Fugerer, Lutz, FL (US); Donald Van der Sluis, Sarasota, FL (US); Craig Hall, Sarasota, FL (US)

Correspondence Address: HOLLAND & HART, LLP, P.O BOX 8749, DENVER, CO, 80201, US

(73) Assignee: SUNOVIA ENERGY TECHNOLOGIES, INC., Sarasota, FL (US)

(21) Appl. No.: 12/598,412

(22) PCT Filed: May 1, 2008
(86) PCT No.: PCT/US08/62311

§ 371 Date: Sep. 17, 2010

Related U.S. Application Data
(60) Provisional application No. 60/915,369, filed on May 1, 2007.

(51) Int. Cl. H01L 31/04

(52) U.S. Cl. 136/259

(57) ABSTRACT

A solar power system includes solar panels placed below-grade and an optical section placed above-grade that collects solar radiation and transmits the solar radiation to the solar panels. The optical section may include optical components and a tracking mechanism. Photovoltaic material may be mounted to one or more surfaces below grade. The surfaces may have a reflective coating that reflects optical radiation that is not absorbed by photovoltaic material of the solar panels such that other solar panels receive the reflected light.

### CROSS REFERENCE TO RELATED APPLICATIONS

This application claims priority from U.S. Provisional Patent Application No. 60/915,369, filed on May 1, 2007, and entitled “System and Method for Collecting and Optically Transmitting Solar Radiation,” the entire disclosure of which is incorporated herein by reference.

### FIELD

The present disclosure related to systems for collecting and converting solar radiation into electricity.

### BACKGROUND

Solar power systems are an attractive form of producing energy from renewable resources. Such systems have recently gained popularity in part because these systems do not require burning of coal or petroleum products to generate electricity, thereby reducing pollution and greenhouse gasses associated with, for example, a traditional coal-fired power generation facility. As such, many individuals and businesses are desirous of having at least a portion of their power needs generated by such systems. Commonly, solar energy collection systems, include a number of solar panels that are mounted to a frame that is secured to the ground, or to a structure. For example, FIG. 1 includes an illustration of a solar power system installed on a structure 10. The system includes solar panels 12 mounted to a portion installed on a structure 10. The system includes solar panels 12 mounted to a portion of a roof 14 of the structure. Such a system may be installed, for example, on a residential or commercial building rooftop and be used to generate at least a portion of the electricity required for the building. In some installations, the system may generate more electricity than is consumed by the building, in which case electricity may be stored or provided to an electric utility. The system includes a number of solar panels 12, with each solar panel 12 including photovoltaic material, electrical components to receive and transmit the electrical energy produced by the photovoltaic material to an interface on the solar panel, and encapsulation material that houses the photovoltaic material and associated electrical components.

While rooftop systems are useful for solar power generation, the location of the solar panels results in a system that is relatively difficult to access, which may result in costly installation and/or servicing. Furthermore, the location of such solar panels exposes the panels to many adverse weather conditions, such as high winds, that may damage the solar panels or structural components that are used to secure the solar panels to the structure. Additionally, many solar power generation systems include solar panels that are mounted to movable structures that may change the orientation of the solar panel(s) so as to provide enhanced generation of electricity by keeping the solar panel(s) oriented at a desired relation to the sun as the sun moves in the sky throughout the day. Such systems, referred to as tracking systems, can significantly increase the power that is output by the associated solar panel(s) as compared to a fixed or static installation. However, such tracking systems require that the solar panel(s) be mounted on a movable frame, which can lead to increased incidences of damage from, for example, high winds.

As is well known, the photovoltaic material that is used in most solar panels has a relatively long lifetime, so long as it is protected from damaging weather elements that may physically damage the photovoltaic material itself. Thus, encapsulation material, which may include transparent materials that transmit solar energy to the photovoltaic material and framing/structural components, is selected to provide suitable protection for the material. However, often the material that is used to encapsulate the photovoltaic material, as well as any associated electrical components in the solar panel, is damaged as a result of, for example, high winds, hail, debris that hits the solar panels as a result of high winds, prolonged exposure to ultraviolet radiation, and excessive heat. In the event that photovoltaic material is exposed to potentially damaging environmental conditions, the efficiency of the photovoltaic material may be reduced, and in some cases the solar panel may fail to produce any electricity.

### SUMMARY

Accordingly, it would be advantageous to provide a solar power system that provides for increased protection of solar panels from environmental conditions while maintaining enhanced efficiency of the photovoltaic material.

Provided herein, in one aspect, is a solar power system that includes solar panels placed below-grade. An optical section is placed above-grade, and collects solar radiation and transmits the solar radiation to the solar panels. The optical section may include optical components and a tracking mechanism. In one embodiment, solar panels are mounted to one or more surfaces. The surfaces may have a reflective coating that reflects optical radiation that is not absorbed by photovoltaic material of the solar panels such that other solar panels receive the reflected light. Power is output from the system that may then be used and/or in any known manner. Such a solar power generation system is usable as an independent generator of DC and/or AC (if equipped with an inverter) power, as part of an array of systems, and may be grid-connected.

### BRIEF DESCRIPTION OF THE DRAWINGS

FIG. 1 is an illustration of a prior art structure having solar panels mounted thereon;

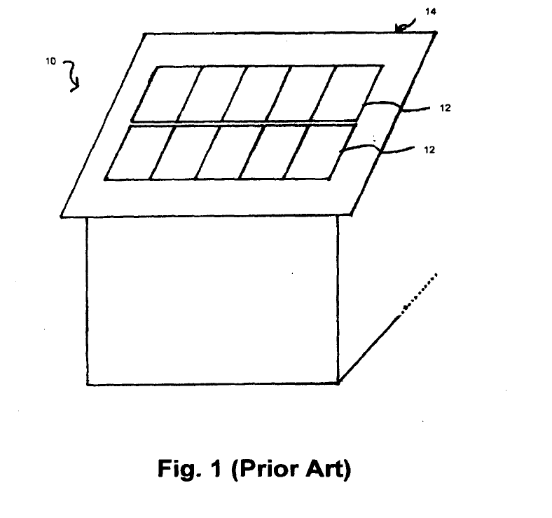

FIG. 2 is an illustration of a solar power system of an embodiment of the disclosure;

FIG. 3 is an illustration of a solar power system of another embodiment of the disclosure;

FIG. 4 is an illustration of a solar power system of yet another embodiment of the disclosure;

FIG. 5 is an illustration of a solar power system of still a further embodiment of the disclosure; and

FIG. 6 is a block diagram illustration of the components of a system of an embodiment of the disclosure.

### DETAILED DESCRIPTION

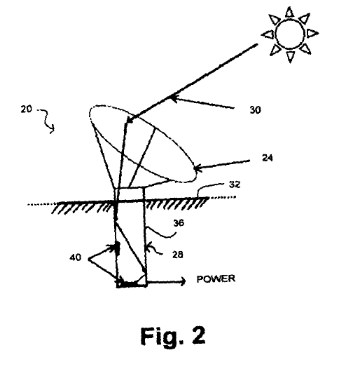

With reference now to FIG. 2, an exemplary embodiment is described. FIG. 2 illustrates a collector 20 that includes an optical section 24 and a photovoltaic section 28. The optical section 24 includes optical components that collect solar radiation, depicted as rays 30 in FIG. 2, and transmits the solar radiation to the photovoltaic section 28. The optical section 24 may include any of a number of different optical components that are suitable for a particular application to collect and transmit solar radiation. In one embodiment, the optical section 24 includes a lens, or set of lenses, that receive solar radiation and focus the radiation on a desired portion of the photovoltaic section 28. The optical section 24 may include a mirror or set of mirrors that receive and transmit solar radiation as desired. Furthermore, a combination of lenses and mirrors may be arranged to collect and focus solar radiation to a desired location in the photovoltaic section 28. The optical section 24 may also have some or all of the optical components mounted on a solar tracking mechanism so as to follow the course of the sun on a daily and seasonal basis, thereby enhancing the efficiency of the collector 20 by collecting an optimal or near optimal amount of available solar radiation. The optical section 24, in some embodiments, also includes a protective dome that is transparent to the desired wavelengths of solar radiation. For example, photovoltaic material in the photovoltaic section 28 may generate optimum solar power at certain concentrations of optical radiation and at certain wavelengths of optical radiation. The optical section 24 may filter and focus solar radiation provided to the photovoltaic section 28 to enhance the operation of the photovoltaic section 24. In one embodiment, the optical section focuses full spectrum solar radiation having a moderate level (5× to 20×) of concentration to the input of the photovoltaic section.

The photovoltaic section 28, in the embodiment of FIG. 2, is housed in a structure that is partially or substantially below the grade of the ground or other surface 32 where the collector 20 is located. The photovoltaic section 28, in this embodiment also forms a support structure for the optical section 24. In the embodiment of FIG. 2, the photovoltaic section includes a housing 36 that has photovoltaic material 40 located on interior surfaces. Solar radiation that is received at the optical section 24 is transmitted to the photovoltaic section 28, and is received at the surface of photovoltaic material 40 in the housing 36. As is understood, presently existing photovoltaic material 40 is generally not 100% absorptive, and thus some of the optical radiation impinging of the surface of the photovoltaic material 40 is reflected and therefore not converted to electrical energy. Also, in embodiments that do not have a continuous layer of photovoltaic material 40, such as embodiments that have discrete photovoltaic cells mounted to the interior of the housing 36, optical radiation that does not hit a photovoltaic cell is not absorbed and converted to electrical power. Furthermore, in some cases, optical radiation impinging on the surface of photovoltaic material 40 may pass through the material and thus not be converted to electrical energy. Also, photovoltaic material 40 may be transparent to certain wavelengths of optical radiation. For example, silicon is transparent to infrared radiation, and thus photovoltaic material fabricated from silicon may be transparent to the infrared portion of the optical radiation provided by the optical section 24. Thus, in some embodiments, the housing 36 is constructed with reflecting surfaces behind the photovoltaic material 40 such that any optical radiation that passes through the photovoltaic material 40 is also reflected back into the photovoltaic material at another portion of the housing 36. Such embodiments include photovoltaic material 40 on various different surfaces of the housing 36. Thus, such embodiments help to mitigate losses that result from optical energy not being absorbed in the first instance by providing multiple reflecting surfaces and photovoltaic surfaces that convert the reflected radiant energy into electrical energy. Furthermore, some embodiments may include photovoltaic materials in the housing that operate at enhanced efficiencies when exposed to solar radiation of certain wavelengths that correspond to the likely wavelengths of reflected solar radiation within the housing 36.

The housing 36 may be a tube having circular or polygonal cross-section which is lined with photovoltaic material 40. Such material may be thin film, rigid, or applied directly by spraying, painting, or by a number of deposition processes. In the case of thin-film or rigid cells, a reflective surface may be applied to the back of the photovoltaic cells prior to installation within the housing 36. In other cases, the photovoltaic material 40 may be sprayed or painted onto the inside of a housing 36 that already has a reflective coating applied.

In operation, solar radiation is received at the optical section 24, where it is focused by optical components within the optical section 24 and transmitted into the photovoltaic section 28. The solar radiation strikes the photovoltaic material 40 within the housing 36 of the photovoltaic section, where some of it is absorbed and turned into electrical energy, and some reflected. The reflected radiation may strike another area of photovoltaic material where, again, some of the energy is absorbed and turned into electrical energy, and some reflected. This process repeats until substantially all of the solar radiation is absorbed and converted into electrical energy. In such a manner, the overall absorption of radiant energy and conversion thereof into electrical energy is enhanced.

As mentioned above, all, or a portion, of the photovoltaic section 36 may be below the surface of the ground, or other surface. In such a manner, photovoltaic material may be shielded from environmental elements that may degrade, damage, or destroy the function of the photovoltaic material. Furthermore, a below-grade installation provides increased protection from wind damage, while still providing a system that enables tracking. The location of such a system also provides increased accessibility compared to rooftop installations, thus reducing installation and/or servicing costs. Furthermore, electrical and encapsulation components associated with photovoltaic material may be shielded from harmful radiation, such as UV radiation. Additionally, the temperature of such a below-grade installation may be regulated more easily to provide an operating temperature that provides enhanced efficiency of the photovoltaic material and/or avoidance of excessive heat that could reduce the lifetime of a solar power system. The optical section may also include one or more filters to provide radiation of desired wavelengths to the photovoltaic section.

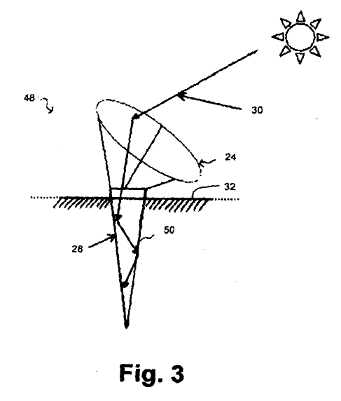

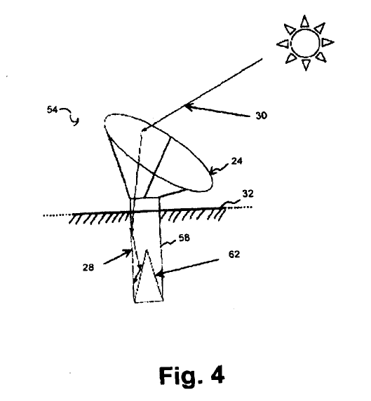

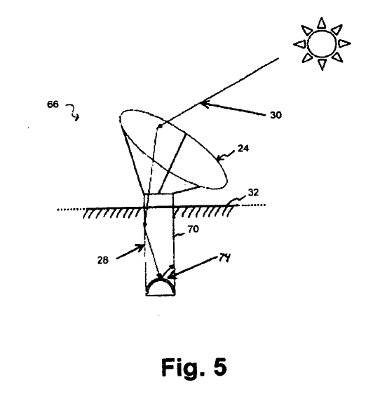

Referring now to FIG. 3, another embodiment is described. In this embodiment, collector system 48 includes an optical section 24 similar to the embodiments described above with respect to FIG. 2. The photovoltaic section 28 of this embodiment includes a tapered housing 50 that includes photovoltaic material on interior surfaces thereof. Similarly as described above, the tapered housing 50 may be coated with reflective material to provide enhanced absorption of radiation that is provided to the photovoltaic section 28. While FIG. 3 illustrates a tapered housing 50, various other configurations of the photovoltaic section 28 may be used in various applications. FIG. 4 illustrates a collection system 54 that includes a photovoltaic section 28 with a housing 58 that also includes an inverted cone 62. The inverted cone 62, in some embodiments may be coated with reflective material, or may also, in other embodiments, include photovoltaic material on all or a portion thereof. Similarly as described above, the inside of the tube housing 58 may be coated with reflective material, and in embodiments where the inverted cone 62 includes photovoltaic material, a coating of reflective material may be placed beneath the photovoltaic material. FIG. 5 illustrates a system 66 of another embodiment, where a housing 70 includes a dome 74 that is covered with reflective material. As will be understood, numerous configurations of the photovoltaic section 28 may be utilized. Similarly, numerous configurations of the optical section 28 may be utilized.

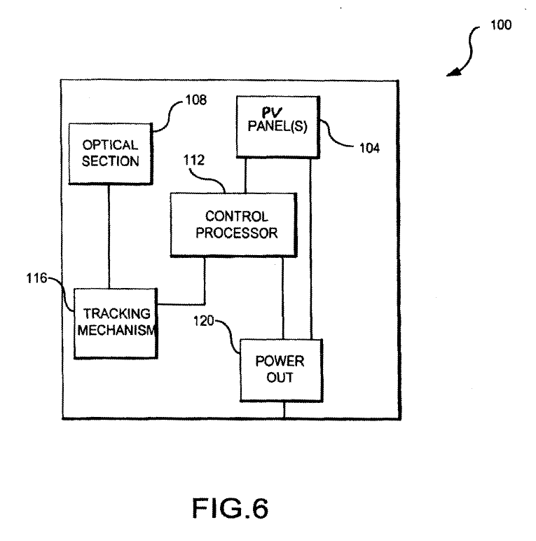

With reference now to FIG. 6, a block diagram illustration of a solar collection system 100 of an embodiment. Illustrated FIG. 6 are photovoltaic (PV) panel(s) 104 that, as described above, may be located in a housing that is located below the grade of the immediately surrounding ground surface. The optical section 108 provides collected solar radiation to the panel(s) 104. In this embodiment, a control processor 112 is interconnected with the panel(s) 104 and to a tracking mechanism 116. The tracking mechanism, as mentioned above, may be mounted between the housing and the optical section and operate to orient the solar radiation collection components of the optical section to provide enhanced output from the panel(s) 104. In one embodiment, the control processor 112 monitors the output of the panel(s) 104 and makes adjustments to the tracking mechanism 116 to provide enhanced power output from the panel(s) 104. For example, the control processor may provide signals to the tracking mechanism 116 that cause the tracking mechanism 116 to adjust the orientation of the optical section 108. The control processor 112 may then monitor the output from the panel(s) 104, and make additional adjustments based on the output from the panel(s) 104 so as to provide optimal output from the panel(s) 104. Such operations may be performed periodically resulting in the orientation of the optical section 108 following the course of the sun on a daily and seasonal basis, thereby enhancing the efficiency of the solar collection system by collecting an optimal or near optimal amount of available solar radiation. The panel(s) 104 and control processor 112, in this embodiment, are also connected to a power output section 120 that transmits the power generated from the panel(s) 104 out of the solar collection system 100. The power output section 120, in an embodiment, provides direct current output that may be used directly or used to charge a storage device such as a battery. The power output section 120, in another embodiment, includes an inverter and provides alternating current output that may be used directly or provided to an electric utility. In other embodiments, the solar collection system 100 may be interconnected both with a storage system and an electric utility, with the power output section 120 providing power in an appropriate form for use in one or both systems. While not illustrated in FIG. 6, the control processor 112 may include, for example, a microprocessor and a memory, with the memory storing operating instructions for the microprocessor to execute to perform the functions as described. Furthermore, the control processor 112 may also include a communications interface, such as a wired or wireless network interface, that may be used to communicate with systems external to the solar collection system 100.

While the instant disclosure has been depicted, described, and is defined by reference to particular exemplary embodiments of the disclosure, such references do not imply a limitation on the disclosure, and no such limitation is to be inferred. The embodiments recited in this disclosure are capable of considerable modification, alteration, and equivalents in form and function, as will occur to those ordinarily skilled in the pertinent arts. The depicted and described embodiments are examples only, and are not exhaustive of the scope of the invention.

The foregoing disclosure sets forth various embodiments via the use of functional block diagrams and examples. It will be understood by those within the art that each block diagram component, operation and/or component described and/or illustrated herein may be implemented, individually and/or collectively, by a wide range of hardware, software, firmware, or any combination thereof. The foregoing disclosure also describes embodiments including components contained within other components (e.g., the various elements shown as components of solar panel). Such architectures are merely examples, and many other architectures can be implemented to achieve the same functionality.

What is claimed is:

1. A solar collection system, comprising:
an optical section configured to receive solar radiation; and
a photovoltaic section coupled to the optical section and configured to receive solar radiation from the optical section, the photovoltaic section comprising:
a housing;
photovoltaic material mounted to the housing, the photovoltaic material adapted to generate electricity from the solar radiation; and
a power output,
wherein the housing is located at least partially below the grade of a surface into which the solar collection system is mounted.

2. The solar collection system, as claimed in claim 1, wherein the optical section comprises at least one focusing lens configured to focus received solar radiation at the photovoltaic section.

3. The solar collection system, as claimed in claim 2, wherein the optical section further comprises at least one filter associated with the focusing lens that permits a selected portion of solar radiation to enter the focusing lens.

4. The solar collection system, as claimed in claim 1, wherein the optical section comprises at least one mirror configured to reflect received solar radiation at the photovoltaic section.

5. The solar collection system, as claimed in claim 1, further comprising:
a tracking system mounted to the photovoltaic section, the optical section mounted to the tracking system, and the tracking system operable to change the orientation of the optical section to provide enhanced solar radiation to the photovoltaic section.

6. The solar collection system, as claimed in claim 1, wherein the photovoltaic section further comprises an inverter that converts electricity provided by the photovoltaic material to alternating current electricity.

7. The solar collection system, as claimed in claim 1, wherein the photovoltaic section further comprises a power storage system.

8. The solar collection system, as claimed in claim 7, wherein the power storage system comprises at least one battery.

9. The solar collection system, as claimed in claim 1, wherein the housing further comprises at least one mirror that reflects solar radiation that is not absorbed by the photovoltaic material to another portion of the photovoltaic material.

10. The solar collection system, as claimed in claim 1, the housing comprises a cylinder and the photovoltaic material is positioned on the interior portions of the cylinder and configured to receive the solar radiation from the optical section.

11. The solar collection system, as claimed in claim 1, the housing comprises a cylinder and an inverted cone located within the cylinder, and the photovoltaic material is positioned on the interior portions of the cylinder and the exterior portions of the inverted cone and configured to receive the solar radiation from the optical section.

12. The solar collection system, as claimed in claim 1, the housing comprises a cylinder and a dome located within the cylinder ad an end thereof opposite the optical section, and the photovoltaic material is positioned on the interior portions of the cylinder and the exterior portions of the dome and configured to receive the solar radiation from the optical section.
